(19) United States
(12) Patent Application Publication
(10) Pub. No.: US 2015/0228503 A1
(43) Pub. Date: Aug. 13, 2015

(54) HARDMASK TRIMMING IN SEMICONDUCTOR FIN PATTERNING

(71) Applicant: Applied Materials, Inc., Santa Clara, CA (US)

(72) Inventors: Ying Zhang, Santa Clara, CA (US); Hua Chung, San Jose, CA (US)

(73) Assignee: Applied Materials, Inc., Santa Clara, CA (US)

(21) Appl. No.: 14/175,379

(22) Filed: Feb. 7, 2014

(51) Int. Cl. H01L 21/3213; H01L 21/033

(52) U.S. Cl. CPC H01L 21/32139; H01L 21/0337

(57) ABSTRACT

Embodiments may involve a method of semiconductor patterning, which includes patterning a first hardmask layer on top of a second hardmask layer. This patterning may define a feature with a first width. The method may encompass reducing the first width to a second width, where the second width is less than or equal to 10 nm. The method may include patterning the second hardmask layer to define a patterned second hardmask layer. The method may involve etching a semiconductor substrate underlying the second hardmask layer to define a fin structure with a third width of less than or equal to 10 nm.

### FIELD

Embodiments of the present technology relate to forming semiconductor fins.

### BACKGROUND

Integrated circuits are made possible by processes which produce intricately patterned material layers on substrate surfaces. Producing patterned material on a substrate requires control led methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity toward a variety of materials.

Etch processes may he termed wet or dry based on the materials used in the process. A wet HF etch preferentially removes silicon oxide over other dielectrics and materials, However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge or if a high enough selectivity is not achievable.

Thus, there is a .need for improved systems and methods that can be used to produce high quality devices and structures. These and other needs arc addressed by the present technology.

### SUMMARY

To increase the density of transistors in microprocessors, semiconductor technology has incorporated On-shaped features as part of the transistor. These fins may form the source, drain, and/or the channel of a transistor and may have the advantage of taking up a smaller area than a conventional field-effect transistor. The dimensions of the fin may he important for transistor performance and reliability. The width of the fin may affect the electrical properties of the transistor, including the threshold voltage and series resistance. The height of the fin also may affect the electrical properties of the transistor, including the drive current and the gate capacitance. Thus, control of the dimensions of the fin may be important to transistor performance.

Embodiments of the present technology may involve a method of semiconductor patterning, which includes patterning a first hardmask layer on top of a second hardmask layer. This patterning may define a feature with a first width. The method may encompass reducing the first width to a second width, where the second width is less than or equal to 10 nm. The method may include patterning the second hardmask layer to define a patterned second, hardmask layer. The method may involve etching a semiconductor substrate underlying the second hardmask. layer to define a fin structure with a third width of less than or equal to 10 nm.

Embodiments may involve a method of semiconductor patterning, which includes patterning a first hardmask layer on top of a second hardmask layer to define a first trench with a first width. The method may further include increasing the first width to a second width, where the second width is less than or equal to 40 nm. The method may involve patterning the second hardmask layer through the first trench. The method may include etching a semiconductor substrate underlying the second hardmask layer to define a second trench. The second trench may have a third width less than or equal to 40 nm.

Embodiments may encompass a method of semiconductor patterning that includes etching an amorphous carbon layer on top of a hardmask layer. The etching of the amorphous carbon layer may define a pair of amorphous carbon features, where each of the pair of amorphous carbon features has a first width. The method may include decreasing the first width to a second width of less than or equal to 10 nm. The pair of amorphous carbon features may have a pitch of less than or equal to 40 nm. The method may include patterning the hardmask layer to define a patterned hardmask layer. A monocrystalline semiconductor substrate underlying the patterned hardmask layer may be etched to form a pair of monocrystalline semiconductor features. The pair of monocrystalline semiconductor features may have a pitch about equal to the pitch of the pair of amorphous carbon features. Each of the pair of monocrystalline semiconductor features may have a width of less than or equal to 10 nm. The method may further involve terming dielectric material between the pair of monocrystalline semiconductor features. The method may include implanting an n-type dopant into the monocrystalline semiconductor substrate. The method may further involve etching the monocrystalline semi conductor substrate to expose an n-type dopant layer, The method may incorporate epitaxially growing a semiconductor material on top of the monocrystalline semiconductor substrate to define a pair of fin structures. The pair of fin structures may contain the semiconductor material and a portion of the monocrystalline semiconductor substrate. The pair of fin structures may nave the same pitch as the pair of monocrystalline semiconductor features. Each of the pair of fin structures may have a fourth width of less than or equal to 10 nm and a height greater than or equal to 150 nm.

Embodiments of the present technology may provide improvements in controlling the width and height of fins in transistors. A narrower fin with a more uniform width may he produced as a result of the processing technology. The fin width may be more uniform along the height of the fin or may be more uniform along the fin's longitudinal axis. The shape may be more rectangular as a result of embodiments of the present technology. The semiconductor material making up the fin may have fewer defects and dislocations. These characteristics and other characteristics of the present technology may lead to better performing and more reliable transistors. Embodiments of the present technology provide these and additional benefits.

### DESCRIPTION OF THE DRAWINGS

A further understanding of the nature and advantages of the disclosed technology may be realized by reference to the remaining portions of the specification and the drawings.

FIGS. 1A-1F show embodiments of cross sections of a semiconductor substrate and other layers.

FIG. 2 shows a method of patterning a semiconductor substrate according to embodiments of the present technology.

FIG. 3 shows a method of patterning a semiconductor substrate according to embodiments of the present technology.

FIGS. 4A-4G depict embodiments for defining fin structures on a substrate utilizing a dopant layer.

FIG. 5 shows a method of patterning a semiconductor substrate according to embodiments of the present technology.

FIG. 6 shows a schematic diagram of a plasma processing apparatus used in etching according to embodiments of the present technology.

### DETAILED DESCRIPTION

Semiconductor patterning may involve patterning an upper layer along with an underlying layer. Semiconductor processing technology may also remove at (east a portion of the upper layer while retaining the underlying layer. Conventional semiconductor processing technology may remove at least some of the upper layer but may still affect the underlying layer. The underlying layer may itself be etched partially away, changing the initially patterned profile. Furthermore, the removal of the upper layer may also deposit contaminants on the underlying layer or affect the structural, electrical, or other properties of the underlying layer. Conventional processing may also require additional processing operations or equipment. These methods may detrimentally degrade the performance of the semiconductor device.

Semiconductor device designs may call for fins with substantially vertical and substantially rectangular cross sections. However, conventional processing may produce fins that have sloped rather than vertical sidewalks, possibly leading to a fin with a wider base than desired. In addition, conventional processing may result in etching or otherwise changing the shape of the top of the fin when attempting to change the angle of the sloped sidewalk Such processing may also leave a polymer residue on fins. Conventional processing with fins may include a concave surface between adjacent fins. This concave surface., which may he an oxide recess, may adversely affect device performance and subsequent processing steps. Conventional processing may include etching the semiconductor substrate, which may be the wafer itself to form fins. The semiconductor substrate may have areas with many fins packed densely together and other areas with no fins or fins spaced farther apart. Fins may be etched to form a flat surface and then replacement semiconductor material may be grown on top to form a fin of a different material. The spacing variation of the fins may result in uneven etching, with some fins being etched more than other fins. Embodiments of the present technology may provide improvements in fin patterning technology.

Turning to FIG, 1A, some embodiments may involve a method of semiconductor patterning, which includes patterning a first hardmask layer 102 on top of a second hardmask layer 104, The second hardmask layer may lie above a semiconductor substrate 106. In these or other embodiments, the first hardmask layer 102 may include amorphous carbon. The first hardmask layer 102 may have a thickness of greater than or equal to 50 nm. The first hardmask layer 102 may be a material that has structural integrity at aspect ratios greater than 3:1.

The second hardmask layer 104 may help feature transfer during the fin structure formation process. In embodiments, the hardmask layer 104 may be a silicon oxide layer, a silicon nitride layer, a silicon oxynitride (SiON) layer, silicon carbide layer, or any suitable organic or inorganic layer, in embodiments, the second hardmask layer 104 may be a silicon nitride layer having a thickness between about 5 nm and about 100 nm, such as about 20 nm and about 40 nm. For example, the thickness may be about 30 nm. The second hardmask 104 layer may contain silicon nitride, while the first hardmask layer 102 may not contain silicon nitride.

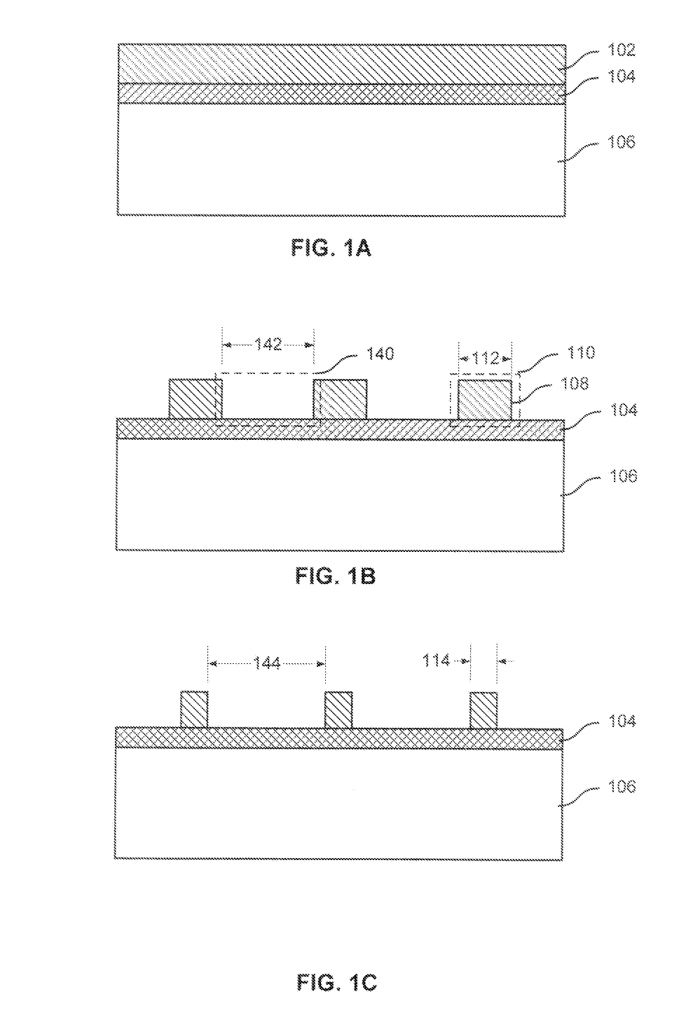

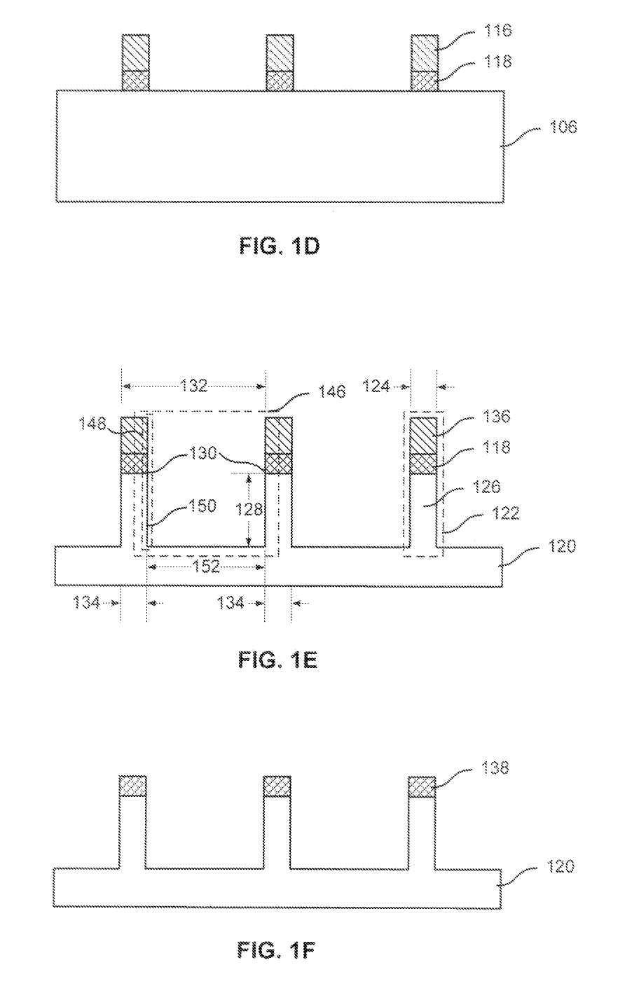

Turning to FIG. 1B, the patterning may define a patterned first hardmask layer 108 that includes a feature 110 with a first width 112, Such patterning may be carried out by photolithography and etching techniques. As shown in FIG, 1C, the method may encompass reducing the first width to a second width 114, where the second width is less than or equal to 10 nm or less than or equal to 7 nm according to embodiments. Reducing the first width to a second width may include dry etch trimming techniques. Such techniques may include increasing the isotropic component of a dry etch. Isotropic etching with plasmas may be enhanced by reducing polymer formation on sidewalls, reducing bias, and/or increasing pressure. Even though the isotropic component of the dry etch is increased, some anisotropic etching of the top of the patterned first hardmask layer 108 may not be avoided. The reduction of the first width to a second width may allow for narrower fin widths than, possible with conventional patterning techniques.

Turning to FIG. 1D, the method may include patterning the second hardmask layer through the patterned first hardmask layer 116 to define a patterned second hardmask layer 118. In some embodiments, the method may further include removing the patterned first hardmask layer 116 and features composed of the patterned first hardmask layer.

As shown in FIG. 1E, the method may involve etching the semiconductor substrate 120 underlying the second hardmask layer to define a fin structure 122 with a third width 124 of less than or equal to 10 nm or less than or equal to 7 nm in embodiments. In some embodiments, the semiconductor substrate 120 may be monocrystalline silicon. The fin structure 122 may include a section of the semiconductor substrate 126, and the section of the semiconductor substrate 126 in the fin structure 122 may have a height 128 greater than or equal to 150 nm or greater than or equal to 100 nm in embodiments. The aspect ratio of the section of the semiconductor substrate 126 in the fin structure 122 may be greater than 10 or greater than 15 according to embodiments. In these or other embodiments, the semiconductor substrate 120 may include a semiconductor wafer. Etching of the semiconductor substrate 120 may include defining a plurality of fin structures 130. The plurality of On structures 130 may have a pitch 132 of less than or equal to 40 nm. Each On structure of the plurality of fin structures 130 may have a fourth width 134, with the fourth width 134 being less than or equal to 10 nm or less than or equal to 7 nm according to embodiments. The first hardmask material 136 may remain on top of the fin structure 122.

Returning to FIG. 1C, die etching process may etch the second hardmask layer 104 along with the substrate 106 in a single step, multiple steps, or separate steps in the same or different etching chambers. In embodiments, the etching process may be performed in an etching processing chamber. The substrate 102 may be etched using the patterned first hardmask layer 116 and the patterned second hardmask layer 118 as an etching mask until the predetermined etching depth is reached in the substrate.

Turning to FIG. 1F, after the substrate etching process, some portion of the patterned second hardmask layer 138 may remain on the substrate 120. The method may limber involve removing the patterned second hardmask layer 138. In embodiments, the method may further include implanting the semiconductor substrate 120 with dopants. In this or other embodiments, the method may involve tilling areas between the plurality of On structures 130 with a dielectric material. The method may include etching the semiconductor material on top of the semiconductor substrate 120, and the semiconductor material may include silicon germanium, germanium, or a III-V compound. Implanting processes will be described in more detail below.

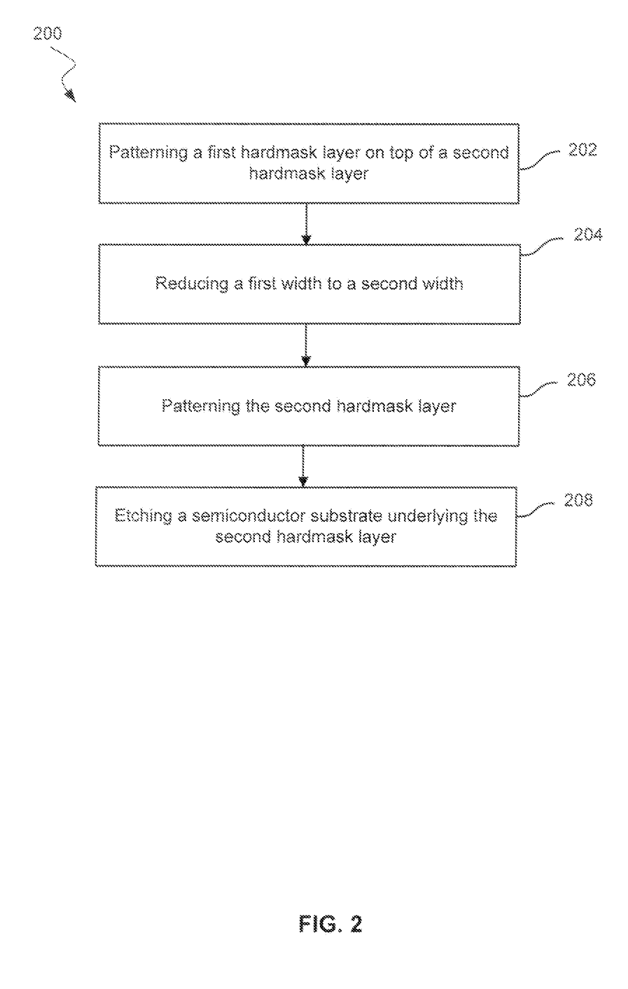

Embodiments of the semiconductor patterning method may occur in the order of the figures, starting with FIG. 1A, then FIG. 1B, and so on, and ending with FIG. 1F. The figures may occur in other orders according to embodiments. Turning to FIG. 2, a semiconductor patterning method 200 may include patterning a first hardmask layer on ton of a second hardmask layer to define a feature with a first width 202. The method 200 may include reducing the first width to a second width 204. In embodiments, the method 200 may involve patterning the second, hardmask layer to define a patterned second hardmask layer 206. and the method 200 may include etching a semiconductor substrate underlying the second hardmask layer 208. This etching may define a fin structure.

Returning to FIG. 1B, embodiments may involve a method of semiconductor patterning, which includes patterning a first hardmask layer 108 on ton of a second hardmask layer 104 to define a first trench 140 with a first width 142.

The method may further include increasing the first width 142 to a second width 144 as shown in FIG. 1C, where the second width 144 is less than or equal to 40 nm, less than or equal to 30 nm, or less than or equal to 25 nm in embodiments. Returning to FIG. 1D, the method may involve patterning the second hardmask layer 118 through the first trench.

Returning to FIG. 1E, the method may include etching a semiconductor substrate 120 underlying the second hardmask layer to define a second trench 146. The second trench may have a sidewalk and a portion of the sidewall 148 may consist of a section of the semiconductor substrate 150. The height 128 of the portion of the sidewall may comprise the section of the semiconductor substrate 150 may be greater than or equal to 100 nm or greater than or equal to 150 nm in embodiments. The portion of the sidewall may consist of the section of the semiconductor substrate according to embodiments.

The second trench 146 may have a third width 152 less than or equal to 40 nm or less than or equal to 30 nm in embodiments. The method may include defining a plurality of second trenches, with a pitch less than or equal to 40 nm, less than or equal to 30 nm, or less than or equal to 25 nm according to embodiments.

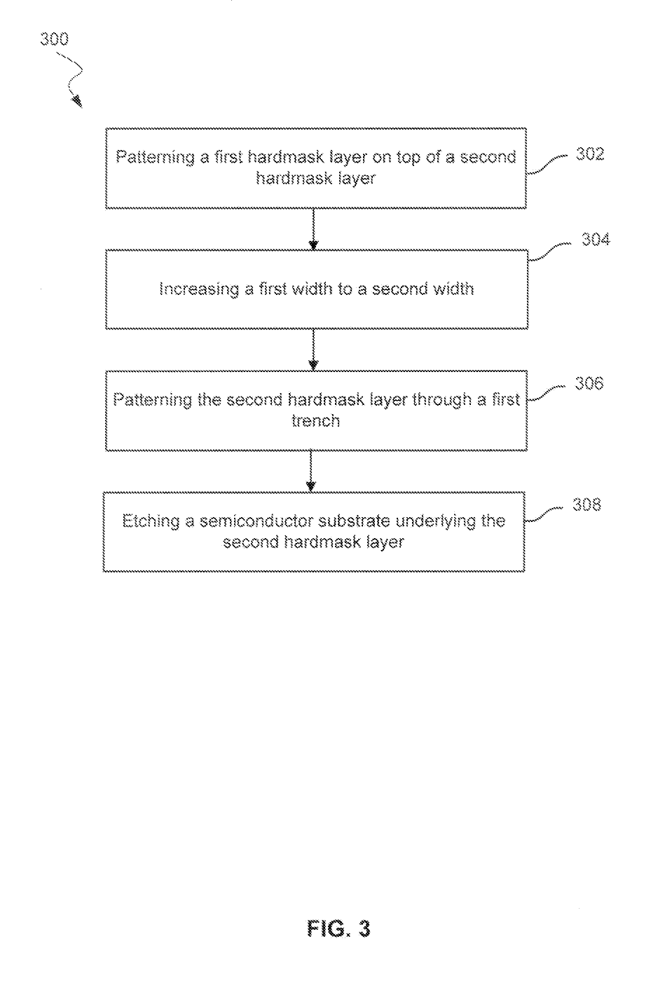

Turning to FIG. 3, embodiments may include a method 300, which includes patterning a first hardmask layer on top of a second hardmask layer 302. The patterning may define a first trench, with a first width. The method 300 may involve increasing the first width to a second width 304 and patterning the second hardmask layer through the first trench 306. The method 300 may include etching a semiconductor substrate underlying the second hardmask layer 308. The etching may define a second trench.

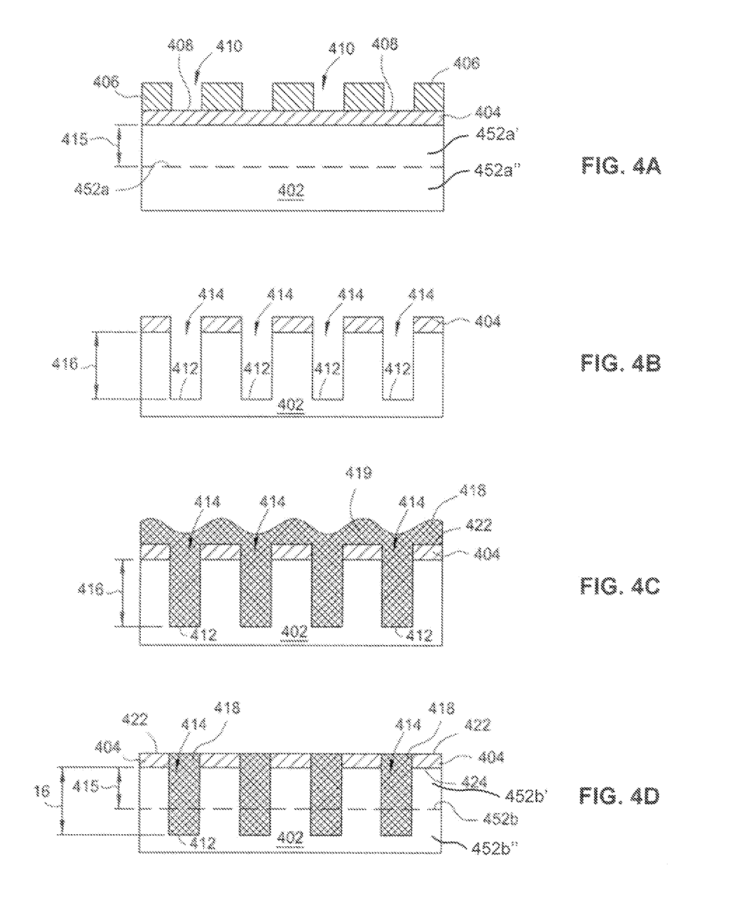

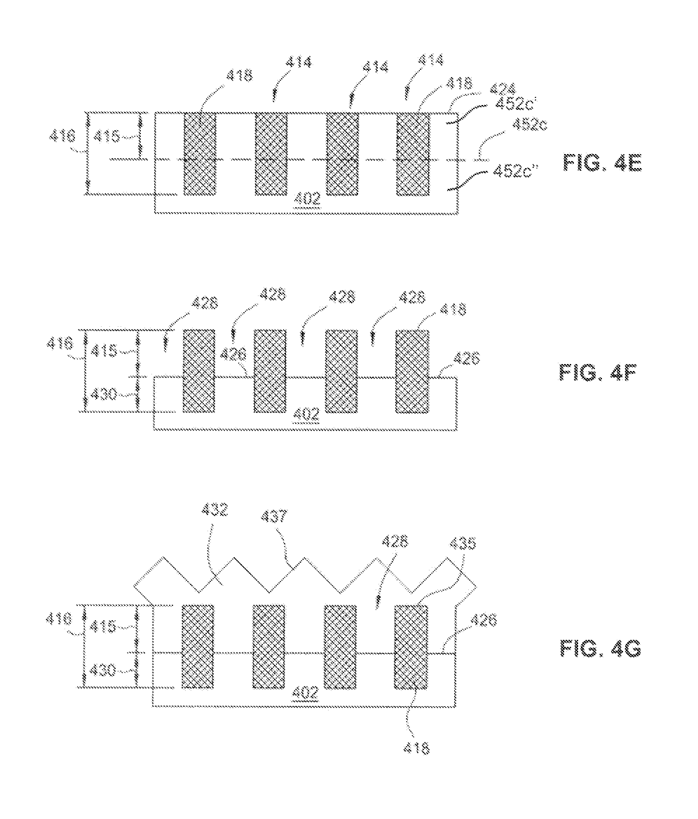

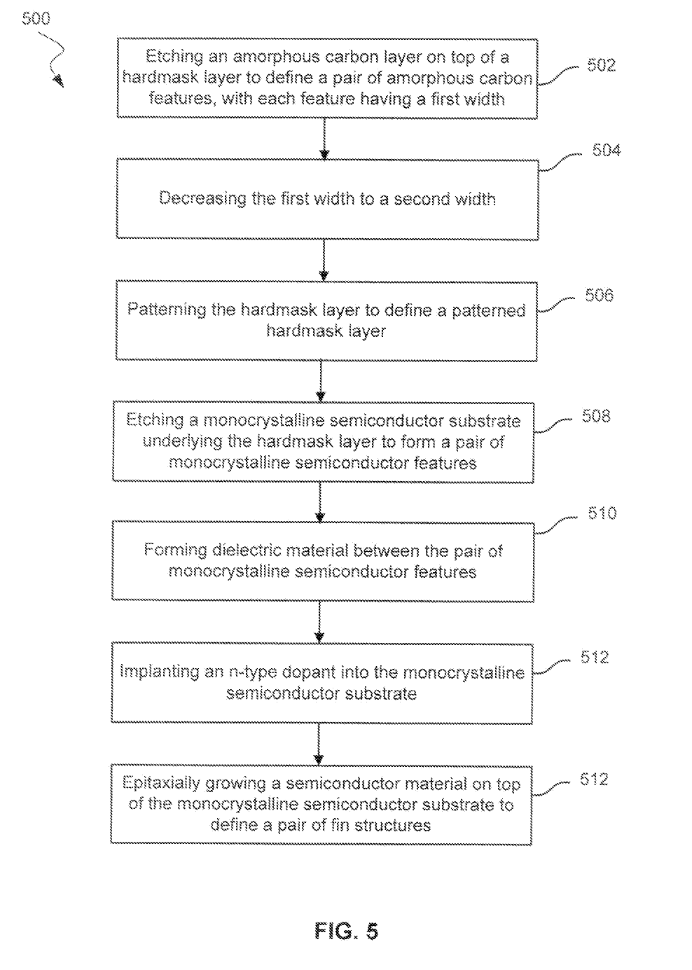

Embodiments may include ion implantation of the semiconductor substrate. Turning to FIG. 4A, embodiments may include providing a substrate 402 having a patterned first hardmask layer 406 and a second hardmask layer 404, disposed thereon. This may be similar to the cross section shown in FIG. 1B. In some embodiments, prior to etching, processing, forming features, or disposing the first hardmask layer 406 on or into the substrate 402, ions may be implanted to a certain doping depth 415 of the substrate 402, as shown as the dotted line 452a, forming a doped area 452a′ therebetween. The doped area 452a′ formed in the substrate 402 having the predetermined doping depth 415 defines a doping layer 452a as a boundary to an undoped region 452a″ in the substrate 402. The doping layer 452a may serve as an etching stop layer during the subsequent silicon recess structure forming process. The doping layer 452a may be formed at different stages during the silicon recess structure manufacturing process, which will be described later with reference to FIGS. 4D and 4E. Details regarding bow the ions may be implanted into the substrate 402 to form the doping layer will be described in greater detail below.

Referring back to FIG. 4A, the patterned first hardmask layer 406 having openings 410 formed therein exposing a surface 408 of the second hardmask layer 404 for etching. In embodiments, the substrate 402 may be a material such as crystalline silicon (e.g., Si<100> or Si‘111’), silicon oxide, strained silicon, silicon germanium, doped or undoped silicon wafers and patterned or non-patterned wafers silicon on insulator (SOI), carbon doped silicon oxides, silicon nitride, doped silicon, germanium, gallium arsenide, glass, or sapphire.

Turning to FIG. 4B, a first etching process is performed to etch the substrate 402 to a predetermined depth 416 in the substrate 402, to form the recess structures 414 in the substrate 402. After etching, a plurality of first silicon recess structures 414 may be formed in the substrate 402. In embodiments, the plurality of first silicon recess structures 414 expose surfaces 412 of the substrate 402 formed in bottom of the recess structures 414. After the substrate etching process, some portion of the second hardmask layer 404 may remain on the substrate 402, which may he removed later in the subsequent process.

Turning to FIG. 4C, after the plurality of recess structures 414 are formed in the substrate 402, an insulating material filling process may be performed to fill the insulating materials 418 into the recess structures 414 in the substrate 402. The insulating materials 418 may be utilized to form shallow trench isolation (STI) structures in the subsequent process so as to facilitate forming semiconductor fins between the STI structures for fin field effect transistors manufacture process.

In embodiments, the insulating material 418 may be a dielectric material, such as silicon oxide material. The insulating material 418 may be formed by a chemical vapor deposition (CVD), a flowable chemical vapor deposition (CVD), a high density plasma (HDP) process, atomic layer deposition (ALD), cyclical layer deposition (CLD), physical vapor deposition (PVD), or the like as needed. In embodiments, the insulating material 418 may be formed by a flowable chemical vapor deposition (CVD).

The flowable CVD process may be performed in a deposition process chamber that may deposit the insulating material 418 utilizing a polysilazanes based silicon containing film (PSZ-like film), which may be reflowable and fillable within trenches, features, vias, recesses or other apertures, such as the recess structures 414, defined in the substrate 402 where the insulating material 418 is deposited. Example precursors for forming the polysilazanes based silicon containing film are silicon-containing precursors including siiane, disilane, methylsilane, dimethylsilane, trimethyisilane, tetramethylsilane, tetraethoxysilane (TEOS), triethoxysilane (TES), octamethylcyelotetrasiloxane (OMCTS), tetramethyhdisiloxane (TMDSO), tetramethylcyclotetrasiloxane (TMCTS), tetramethyl-diethoxyl-disiloxane (TMDDSO), dimethyl-dimethoxyl-silane (DMDMS) or combinations thereof. Additional precursors for the deposition of silicon nitride include SiₓN_{y}H_{z}-containing precursors, such as silyl-amine and its derivatives including trisilylamine (TSA) and disilylainine (DSA), SiₓN_{y}H_{z}O_{zz}-containing precursors, SiₓN_{y}H_{z}Cl_{zz}-containing precursors, or combinations thereof.

After the insulating material 418 has filled in the recess structures 414 of the substrate 402, a baking process may be performed to density the insulating material 418. The baking process may allow the insulating material 418 formed on the substrate to become flowable, and to reflow and uniformly fill within the recess structures 414. It is believed that the baking process can assist maintaining the film formed on the substrate surface in a liquid-like flowable state, so as to preserve the flowability and viscosity of the resultant film formed thereon, facilitating complete filling of the insulating material 418 into the recess structures 414 and leaving a recess portion 419 of the insulating material 418 disposed over an surface 422 of the second hardmask layer 404, which will be removed later in the process.

After or prior to the recess portion 419 of the insulating material 418 and/or the second hardmask layer 404 is removed from the substrate 402, an ion implantation process may be performed to implant dopants into the substrate 402 forming doped areas 452b′ (as shown in 4D), or 452c′ (as shown in FIG. 4E) defining a doping layer 452b (as shown in FIG. 4D) or a doping layer 452c (as shown in FIG. 4E) in Ore substrate 402 with the predetermined doping depth 415. It is noted that the doping layer 452a (as shown in FIG. 4A), 452b (as shown in FIG. 4D), 452c (as shown in FIG, 4E) may be formed at any stages when manufacturing silicon recess structures in the substrate 402. The doping layer 452a, 452b, 452c may be formed in any order or in any stage based on different process sequence arrangements.

During the ion implantation process, dopants with different ion properties are implanted and driven into the substrate 402. The dopants in the doping area 452a′, 452b′ or 452c′ defining the doping layer 452a, 452b, 452c, which, serves as a block layer/etching stop layer that prevents the substrate 402 from overcoming when reaching to the doping layer 452a, 452b, 452c. Without intending to be bound by theory, it is believed that the dopants implanted into the doping area 452a′, 452b′, or 452c′ may react with the etchant at a faster (or slower) etching rate to enhance the etching selectivity, as compared to the undoped area 452a″, 452b″, or 452c″ in the substrate. By utilising the etching rate difference between the doping area 452a′, 452b′ or 452c′ and undoped area 452a″, 452b″ or 452c″ in the substrate 402, a natural etching barrier, the defined doping layer 452a, 452b. 452c, may be formed as an etching stop layer/blocking layer to efficiently control an etching stop point during the etching process. For example, when n-type dopants are selected to be Impinged into the silicon lattice structures to form the doped area 452a′, 452b′ or 452c′ on the substrate 402, the n-type dopants may be inserted into the interstitial, sites between, the silicon atoms in the lattice structure, changing the Fermi level of Si substrate with n-type dopants, resulting in the bandgap of n-doped silicon in the doped, areas 452a′, 452b′, 452c′ close to the conduction band. Such n-type dopants doped in the doped areas 452a′, 452b′, 452c′ may provide free electrons during the etching process. As such, when a halogen containing gas, such as a chlorine containing gas, is utilized during the etching process, the tree electron provided from the n-type dopants in the silicon tends to rapidly react with, the chlorine containing gas through, electron transfer process (i.e., as chlorine containing gas is known to have it high tendency for grabbing electron during a chemical reaction), efficiently increasing silicon substrate etch rate.

As compared to the undoped area 452a″, 452b″, 452c″ (e.g., intrinsic silicon areas or lightly p-type doped areas) without n-type dopants, lack of free electrons as a media for promoting chemical reaction may result in significantly low etching rate, creating a natural reaction barrier (at the interface of the doping layer 452a, 452b, 452c) to prevent the etchants from further etching when reaching to the undoped area 452a″, 452b″, 452c″ with relatively low etching rate. Accordingly, the doping layer 452a, 452b, 452c defined by the doped areas 452a′, 452b′, 452c′ serves as an etching stop layer that prevents the ions from the etchant to penetrate through. Therefore, by selecting proper ions to be doped in the substrate 402, an efficient, etching stop layer may be created to provide an etching process with high selectivity, such as greater than 1000. Thus, the high electivity of the etching process may assist forming desired etch front profile and to minimize etch depth, variations in areas of different pattern densities to eliminate undesired microloading effects and obtain a recess structure profile (e.g., trenches, recess structures, features, vias, holes, or the like) in the substrate 402 with desired dimension (e.g., depth and width of the structure) and. sidewall/bottom management.

In embodiments, tire dopants selected to be implanted into the substrate 402 may be n-type dopants, such as Sb, As, P, and N. In embodiments wherein the n-type dopants are utilized, Sb may be selected as the dopant as tire higher molecular weight of Sb may assist the dopants to stay at a desired lattice structure in the substrate without undesired drift, during an etching process. In some embodiments, p-type dopants, such as B, Ah Ga, and in, may be utilized based on different process requirements, in embodiments, the dopants selected to be implanted into the substrate 402 are n-type dopants selected from a group consisting of Sb, As, P, and N. In embodiments, the dopants may be implanted into the substrate 402 with the predetermined depth 415 between about 50 nm and about 500 nm, such as between about 50 nm and about 300 nm from a surface 424 of the substrate 402, as shown in FIGS. 4D and 4E. The predetermined depth 415 defined in the substrate 402 may be shorter than the depth 416 defined in the recess structure 414 so as to form silicon recess structures among the STI structures.

In embodiments, the dopants may be doped into the substrate 402 using any suitable techniques, such as by using a beam ion implantation process, plasma immersion ion implantation process, or other suitable implantation process. A conventional ion implantation process may also utilized to implant ions into the substrate 402 to form doped areas 452a′, 452b′, 452c′ defining the doping layer 452a, 452b, 452c.

In one example, the dopants are doped into the substrate 402 using a plasma immersion implantation process. Plasma immersion implantation may implant ions shallow in the substrate 402 and may cause bonding structure change in the implanted area. The degree of change may be selected by tuning the depth of the implant. The size of ions being implanted will also affect the energy needed to implant ions to a given depth. The ions provided in a plasma immersion ion implantation process, as described herein, may be generated from a plasma formed by applying a high voltage RF or any other forms of EM field (microwave or DC) to a processing chamber. The plasma dissociated ions may then biased toward the substrate surface and implanted into a certain desired depth from the substrate surface.

After the doped areas 452a′, 452b′, 452c′ are formed in the substrate 402 defining the doping layer 452a, 452b, 452c, an optional annealing process may be performed to activate the dopants as implanted therein as well as to secure the dopants at desired lattice sites in the substrate as needed. In embodiments, the annealing process may have an annealing temperature between about 600 degrees and about 1500 degrees Celsius.

An etching process or a polishing process may be performed remove the excess portion 419 of the insulating material 418 from the substrate 402, as shown in FIG. 4D, to expose the underlying second hardmask layer 404. The second hardmask layer 404 may be removed to expose the upper surface 424 of the substrate 402, having the insulating material 418 filled in the recess structures 414 without covering the upper surface 424 of the substrate 402, as shown in FIG. 4E.

In embodiments, the etching process or the polishing process may be a one-step etching/polishing process to remove both the excess portion 419 of the insulating material 418 and the second hardmask layer 404 simultaneously, in these or other embodiments, the etching process or the polishing process may be a multiple step etching/polishing process to remove the excess portion 419 of the insulating material 418 and the second hardmask layer 404, separately at different stages of the etching process or the polishing process. In embodiments, the excess portion 419 of the insulating material 418 and the second hardmask layer 404 are removed by a chemical mechanical polishing (CMP) process.

After at least one of the doping layers 452a, 452b, 452c are formed in the substrate 402, a second etching process may be performed to form a second recess structure 428 to remove portion of the substrate 402 between the Insulating materials 418, which may be utilized as shallow trench isolation (STI) structures, as shown in FIG. 4F. In this particular etching process, the doping layers 452a, 452b, 452c may be utilized as an etching stop layer/blocking layer to provide the etching process an ending boundary in the substrate 402 from overetching. The aggressive etchants from the etching process may continue to etch the substrate 402 until a surface 426 defined by one of the doping layers 452a, 452b, 452c having a predetermined depth 415 in the substrate 402 is reached and the etching process may then be terminated. In embodiments, the predetermined depth 415 may be slightly shorter than the depth 416 where the recess structure 414 where the insulating material 418 is filled. This depth difference 430 may be between about 50 nm and about 300 nm.

The etching process etches the silicon materials from the substrate 402 defined between the insulating materials 418, forming the second recess structures 428 in the substrate 402. The second recess structures 428 formed in the substrate 402 may then be utilized to form semiconductor fins, when the semiconductor fin may be desired to be from a material different from the material made from the substrate 402.

The dopants utilized to form the doping layer 452a, 452b, or 452c may also be removed when exposed during the second silicon recess structure etching process. The exposed surface 426 of the substrate 402 may already have the dopants utilized to define the doping layer 452a, 452b, or 452c removed from the substrate 402.

After the second silicon recess structures 428 are formed in the substrate 402 in between the insulating materials 418, a deposition process may be performed to deposit/fill a desired material 432 into the recess structure 428. Examples of suitable desired material 432 to be filled into the second silicon recess structures 428 may be silicon germanium (SiGe), Ge containing layer, Group III-V materials, doped or undoped amorphous silicon materials, doped crystalline silicon materials, and the like. Material 432 may also be grown epitaxially. Insulating material 435 may be between material 432. Uneven or extra growth 437 of material 432 may later be removed or evened by further processing. Embodiments of the semiconductor patterning method may occur in the order of the figures, starting with FIG. 4A, then FIG. 4B, and so on, and ending with FIG. 4G. The figures may occur in other orders according to embodiments.

Turning to FIG, 5, embodiments may encompass a method 500 of semiconductor patterning that includes etching an amorphous carbon layer on top of a hardmask layer 502. The etching of the amorphous carbon layer may define a pair of amorphous carbon features, where each of the pair of amorphous carbon features has a first width. The method 500 may include decreasing the first width to a second width of less than or equal to 10 nm 504. The pair of amorphous carbon features may have a pitch of less than or equal to 40 nm. The method 500 may include patterning the hardmask layer to define a patterned hardmask layer 506. A monocrystalline semiconductor substrate underlying the patterned hardmask layer may be etched to form a pair of monocrystalline semiconductor features 508. The pair of monocrystalline semiconductor features may have a pitch about equal to the pitch of the pair of amorphous carbon features. Each of the pair of monocrystalline semiconductor features may have a width of less than or equal to 10 nm. The method 500 may further involve forming dielectric material between the pair of monocrystalline semiconductor features 510.

The method 500 may include implanting an n-type dopant into the monocrystalline semiconductor substrate 512. The method 500 may further involve etching the monocrystalline semiconductor substrate to expose an n-type dopant layer. The method 500 may incorporate epitaxially growing a semiconductor material on top of the monocrystalline semiconductor substrate to define a pair of fin structures 512. The pair of fin structures may contain the semiconductor material and a portion, of the monocrystalline semiconductor substrate. The pair of fin structures may have the same pitch as the pair of monocrystalline semiconductor features. Each of the pair of fin structures may have a fourth width of less than or equal to 10 nm. The portion of each of the pair of the fin structures that consists of semiconductor material may have a height greater than or equal to 150 nm or greater than or equal to 100 nm in embodiments.

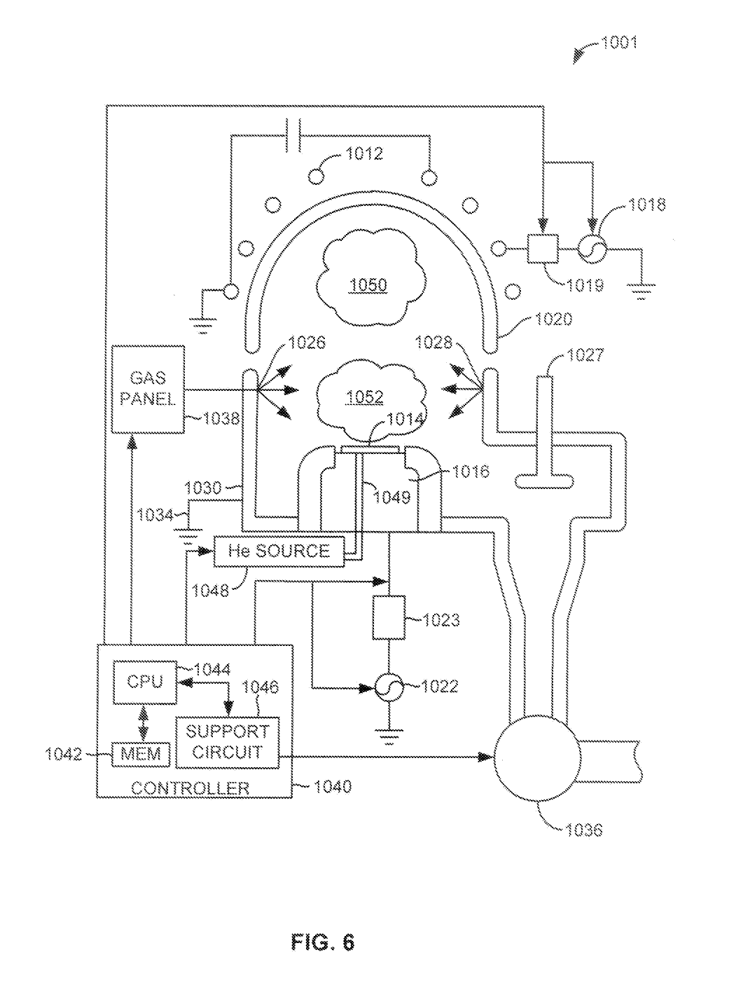

FIG. 6 depicts a schematic diagram of one embodiment of an illustrative etch process chamber 1001. Chamber 1001 may be a MESA chamber available from Applied Materials, inc. of Santa Clara, Calif. The chamber 1001 includes a conductive chamber wall 1030 that supports a dielectric dome-shaped ceiling (referred hereinafter as the dome 1020). Other chambers may have other types of ceilings (e.g., a flat ceiling). The wall 1030 is connected to an electrical ground 1034.

At least one inductive coil antenna segment 1012 is coupled to a radio-frequency (RF) source 1018 through a matching network 1019. The antenna segment 1012 is positioned exterior to the dome 1020 and is utilized to maintain a plasma formed from process gases within the chamber. In one embodiment, the source RF power applied to the inductive coil antenna 1012 is in a range between about 0 Watts to about 2500 Watts at a frequency between about 50 kHz and about 13.56 MHz. In another embodiment, the source RF power applied to the inductive coil antenna 1012 is in a range between about 200 Watts to about 800 Watts, such as at about 400 Watts.

The process chamber 1001 also includes a substrate support pedestal 1016 (biasing element) that Is coupled to a second (biasing) RF source 1022 that is generally capable of producing an RF signal to generate a bias power about 1500 Warts or less (e.g., no bias power) at a frequency of approximately 13.56 MHz. The biasing source 1022 is coupled to the substrate support pedestal 1016 through a matching network 1023. The bias power applied to the substrate support pedestal 1016 may be DC or RF.

In operation, a substrate 1014 is placed on the substrate support pedestal 1016 and is retained thereon by conventional techniques, such as electrostatic chucking, vacuum, or mechanical clamping. Gaseous components are supplied from a gas panel 1038 to the process chamber 1001 through entry ports 1026 and 1028 to form a gaseous mixture 1050. A plasma, formed from the mixture 1050, is maintained in the process chamber 1001 by applying RF power from the RF sources 1018 and 1022, respectively, to the inductive coil 1012 and the substrate support pedestal 1016. Ions are accelerated using RF source 1022 toward substrate 1014 which is located in substrate processing region 1052. The pressure within the interior of the etch chamber 1001 is controlled using a throttle valve 1027 situated between the chamber 1001 and a vacuum pump 1036. The temperature at the surface of the chamber wails 1030 is controlled using liquid-containing conduits (not shown) that are located in the walls 1030 of the chamber 1001.

The temperature of the substrate 1014 is controlled by stabilizing the temperature of the support pedestal 1016 and flowing a heat transfer gas from source 1048 via conduit 1049 to channels formed by the back of the substrate 1014 and grooves (not shown) on the pedestal surface. Helium gas may be used as the heat transfer gas to facilitate heat transfer between the substrate support pedestal 1010 and the substrate 1014. Helium disposed between the pedestal 1016 and substrate 1014 facilitates uniform beating of the substrate 1014. Using thermal control of both the dome 1020 and the substrate support pedestal 1016, the substrate 1014 may be maintained at a temperature of between about 100 degrees Celsius and about 500 degrees Celsius.

Those skilled in the art will understand that other forms of etch chambers may be used. For example, chambers with remote plasma sources, microwave plasma chambers, electron cyclotron resonance (ECR) plasma chambers, and the like may be utilized.

A controller 1040, including a central processing unit (CPU) 1044, a memory 1042, and support circuits 1046 for the CPU 1044, is coupled to the various components of the DPS etch process chamber 1001 to facilitate control of the etch process. To facilitate control of the chamber as described above, the CPU 1044 may be one of any form of general purpose computer processor that can be used in an industrial setting for controlling various chambers and subprocessors. The memory 1042 is coupled to the CPU 1044. The memory 1042, or computer-readable medium, may be one or more of readily available memory such as random access memory (RAM), read only memory (ROM), floppy disk, hard disk, USB flash drive, or any other form of digital storage, local or remote. The support circuits 1046 are coupled to the CPU 1044 for supporting the processor in a conventional manner. These circuits include cache, power supplies, clock circuits, input/output circuitry and subsystems, and the like. An etching process, such as described herein, is generally stored in the memory 1042 as a software routine. The software routine may also be stored and/or executed by a second CPU (not shown) that is remotely located from the hardware being controlled by the CPU 1044.

In the preceding description, for the purposes of explanation, numerous details have been set forth to provide an understanding of various embodiments of the present technology. It will be apparent to one skilled in the art, however, that certain embodiments may he practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described to avoid unnecessarily obscuring the present technology. Accordingly, the above description should not be taken as limiting the scope of the technology.

Where a range of values is provided, it is understood that each intervening value, to the smallest fraction, of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within die technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a fin” includes a plurality of such fins, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of semiconductor patterning comprising:
patterning a first hardmask layer on top of a second hardmask layer to define a first feature with a first width;
reducing the first width to a second width, wherein the second width is less than or equal to 10 nm;
patterning the second hardmask layer to define a patterned second hardmask layer; and
etching a semiconductor substrate underlying the second hardmask layer to define a fin structure with a third width of less than or equal to 10 nm.

2. The method of claim 1, wherein the first hardmask layer comprises amorphous carbon.

3. The method of claim 1, wherein the semiconductor substrate comprises a semiconductor wafer.

4. The method of claim 1, wherein etching the semiconductor substrate comprises defining a plurality of fin structures, wherein each fin structure of the plurality of fin structures has a fourth width of less than or equal to 10 nm.

5. The method of claim 4, wherein the plurality of fin structures has a pitch of less than or equal to 40 nm.

6. The method of claim 1, wherein the fin structure comprises a section of the semiconductor substrate, wherein the section of the semiconductor substrate has a height greater than or equal to 150 nm.

7. The method of claim 1, wherein the fin structure comprises a section of the semiconductor substrate, wherein the section of the semiconductor substrate has a height greater than or equal to 100 nm.

8. The method of claim 1, wherein the method further comprises removing the patterned second hardmask layer.

9. The method of claim 1, wherein the second hardmask layer has a thickness of less than or equal to 30 nm.

10. The method of claim 1, wherein the first hardmask layer has a thickness of greater than or equal to 50 nm.

11. The method of claim 4, wherein the method further comprises:
implanting the semiconductor substrate with dopants;
filling areas between the plurality of fin structures with a dielectric material;
etching the semiconductor substrate to expose a layer of dopants; and
epitaxially growing semiconductor material on top of the semiconductor substrate.

12. The method of claim 11, wherein the semiconductor material comprises silicon germanium, germanium, or a III-V compound.

13. The method of claim 1, wherein the second hardmask layer comprises silicon nitride and the first hardmask layer does not comprise silicon nitride.

14. The method of claim 1, wherein the semiconductor substrate is monocrystalline silicon.

15. The method of claim 1, wherein the method further comprises removing the first feature.

16. A semiconductor patterning method, comprising:
patterning a first hardmask layer on top of a second hardmask layer to define a first trench having a first width;
increasing the first width to a second width, wherein the second width is less than or equal to 40 nm;
patterning the second, hardmask layer through the first trench; and
etching a semiconductor substrate underlying the second hardmask layer to define a second trench with a third width of less than or equal to 40 nm.

17. The method of claim 16, wherein etching the semiconductor substrate comprises defining a plurality of second trenches with a pitch less than or equal to 40 nm.

18. The method of claim 16, wherein etching the semiconductor substrate comprises defining a plurality of second trenches, wherein the plurality of second trenches has a pitch of less than or equal to 25 nm.

19. The method of claim 16, wherein:
the second trench has a sidewall;
a portion of the side-wall consists of a section of the semiconductor substrate; and
the portion of the sidewall has a height of greater than or equal to 150 nm.

20. A method of semiconductor patterning, comprising:
etching an amorphous carbon layer on top of a hardmask layer to define a pair of amorphous carbon features, wherein each of the pair of amorphous carbon features has a first width;
decreasing the first width to a second width, wherein the second width is less than or equal to 10 nm and the pair of amorphous carbon features has a pitch of less than or equal to 40 nm;
patterning the hardmask layer to define a patterned hardmask layer;
etching a monocrystalline semiconductor substrate underlying the hardmask layer to form a pair of monocrystalline semiconductor features, wherein;
the pair of monocrystalline semiconductor features is characterized by the pitch of less than or equal to 40 nm, and
each of the pair of monocrystalline semiconductor features has a third width of less than or equal to 10 nm;
forming dielectric material between the pair of monocrystalline semiconductor features;
implanting an n-type dopant into the monocrystalline semiconductor substrate;
etching the monocrystalline semiconductor substrate to expose an n-type dopant layer; and
epitaxially growing a semiconductor material on top of the monocrystalline semiconductor substrate to define a pair of fin structures comprising the semiconductor material and a portion of the monocrystalline semiconductor substrate, wherein:
the pair of fin structures is characterized by the pitch of less than or equal to 40 nm, and
each of the pair of fin structures has a fourth width of less than or equal to 10 nm.
